(19) United States
(12) Patent Application Publication
(10) Pub. No.: US 2012/0299140 A1
(43) Pub. Date: Nov. 29, 2012

(54) SOLID-STATE IMAGING DEVICE, METHOD FOR MANUFACTURING SOLID-STATE IMAGING DEVICE, AND CAMERA MODULE

(75) Inventor: Hirokazu SEKINE, Fujisawa-shi (JP)

(73) Assignee: Kabushiki Kaisha Toshiba, Tokyo (JP)

(21) Appl. No.: 13/417,465

(22) Filed: Mar. 12, 2012

(30) Foreign Application Priority Data
May 26, 2011 (JP) 2011-118015

(51) Int. Cl. H01L 31/0232; H01L 31/18

(52) U.S. Cl. 257/432; 438/65; 257/E31.127

(57) ABSTRACT

Certain embodiments provide a solid-state imaging device including a curved guide having a curved portion of a concave shape, a sensor substrate, an adhesive, a transparent substrate, and an external electrode. The sensor substrate includes a sensor section, for receiving light collected by a lens and generating charges in accordance with a light receiving quantity, on a surface, has the curved guide fixed on a back surface, and has a region including the sensor section curved downward to a convex shape along the curved portion of the curved guide. The adhesive is formed at a periphery of the sensor section. The transparent substrate is a plate-like substrate fixed on the sensor substrate by the adhesive. The external electrode is formed on the back surface of the sensor substrate, and is electrically connected to the sensor section through a through-electrode provided on the sensor substrate.

### CROSS REFERENCE TO RELATED APPLICATIONS

This application is based upon and claims the benefit of priority from the prior Japanese Patent Application No. 2011-118015 filed in Japan on May 26, 2011; the entire contents of which are incorporated herein by reference.

### FIELD

Embodiments described herein relate generally to a solid-state imaging device, a method for manufacturing the solid-state imaging device, and a camera module.

### BACKGROUND

A solid-state imaging device mounted in a camera such as a small camera module in a portable telephone and the like and a digital camera of the prior art mounted includes a sensor substrate in which a sensor section for receiving the light collected by a lens is formed on a surface of a planar silicon substrate.

A focal plane formed by a focus position of a lens is a curved rotation surface. Therefore, misalignment occurs between the curved focal plane and the planar sensor section. This misalignment becomes a factor that inhibits higher quality of the solid-state imaging device, the camera module, and the camera.

### BRIEF DESCRIPTION OF THE DRAWINGS

FIG. 1 is an explanatory view for describing the principle of the present invention;

FIG. 2 is a cross-sectional view showing a camera module according to a first embodiment;

FIG. 3 is a cross-sectional view for describing a method for manufacturing the solid-state imaging device according to the first embodiment, and is a view showing a step of thinning the sensor substrate;

FIG. 4 is a cross-sectional view for describing the method for manufacturing the solid-state imaging device according to the first embodiment, and is a view showing a step of forming an external electrode;

FIG. 5 is a cross-sectional view for describing the method for manufacturing the solid-state imaging device according to the first embodiment, and is a view showing a step of suctioning gas in a second space between the sensor substrate and a curved guide;

FIG. 6 is a cross-sectional view for describing the method for manufacturing the solid-state imaging device according to the first embodiment, and is a view showing a step of bringing the sensor substrate into contact with the curved guide;

FIG. 7 is a cross-sectional view for describing a method for manufacturing the camera module according to the first embodiment, and is a view showing a step of fixing a lens holder on the solid-state imaging device;

FIG. 8 is a cross-sectional view corresponding to FIG. 2 showing a solid-state imaging device to be applied to a camera module according to a second embodiment;

FIG. 9 is a cross-sectional view describing a method for manufacturing the solid-state imaging device according to the second embodiment, and is a view showing a step of suctioning the air in a vacuum container;

FIG. 10 is a cross-sectional view describing the method for manufacturing the solid-state imaging device according to the second embodiment, and is a view showing a step of bringing a sensor substrate into contact with a curved guide;

FIG. 11 is a cross-sectional view showing a variant of the step shown in FIG. 10;

FIG. 12 is a cross-sectional view showing another variant of the step shown in FIG. 10;

FIG. 13 is a cross-sectional view showing a solid-state imaging device to be applied to a camera module according to a third embodiment;

FIG. 14 is a cross-sectional view describing a method for manufacturing the solid-state imaging device according to the third embodiment, and is a view showing a step of forming a first adhesive;

FIG. 15 is a cross-sectional view of the first adhesive taken along a chain dashed line X-X′ of FIG. 14;

FIG. 16 is a cross-sectional view describing the method for manufacturing the solid-state imaging device according to the third embodiment, and is a view showing a step of suctioning the air in a second space between the sensor substrate and the curved guide;

FIG. 17 is a cross-sectional view showing a solid-state imaging device to be applied to a camera module according to a fourth embodiment;

FIG. 18 is a top view showing a curved guide applied to a method for manufacturing the solid-state imaging device according to the fourth embodiment;

FIG. 19 is a cross-sectional view of the curved guide taken along a chain dashed line Y-Y′ of FIG. 18;

FIG. 20 is a cross-sectional view describing the method for manufacturing the solid-state imaging device according to the fourth embodiment, and is a view showing a step of fixing the curved guide to the back surface of the silicon wafer;

FIG. 21 is a cross-sectional view describing the method for manufacturing the solid-state imaging device according to the fourth embodiment, and is a view showing a step of discharging gas in a plurality of second spaces formed by the silicon wafer and the curved guide; and

FIG. 22 is a cross-sectional view describing the method for manufacturing the solid-state imaging device according to the fourth embodiment, and is a view showing a step of cutting the glass wafer, the second adhesive, the silicon wafer, and the curved guide.

### DETAILED DESCRIPTION

Certain embodiments provide a solid-state imaging device including a curved guide, a sensor substrate, an adhesive, a transparent substrate, and an external electrode. The curved guide has a curved portion of a concave shape. The sensor substrate has, on the surface, a sensor section for receiving the light collected by the lens and generating charges according to the light receiving quantity, where the curved guide is fixed on a back surface and a region including the sensor section is curved downward to a convex shape along the curved portion of the curved guide. The adhesive is formed at a periphery of the sensor section in the surface of the sensor substrate. The transparent substrate is a plate-like substrate fixed on the sensor substrate by the adhesive. The external electrode is formed on the back surface of the sensor substrate, and is electrically connected to the sensor section through a through-electrode provided on the sensor substrate.

Certain embodiments provide a camera module including the solid-state imaging device described above, a tubular lens holder, a lens, and a tubular shield. The lens holder is fixed on the transparent substrate of the solid-state imaging device. The lens is held in the lens holder. The shield is fixed to the lens holder and is arranged to cover the sensor substrate and the transparent substrate.

Certain embodiments provide a method for manufacturing a solid-state imaging device including forming an adhesive, forming a first space, thinning a back surface of a sensor substrate, forming an external electrode, forming a second space, and bringing a curved guide into contact with the back surface of the sensor substrate. The adhesive is formed at a periphery of a sensor section in the surface of the sensor substrate including the sensor section for receiving the light collected by the lens and generating charges according to a light receiving quantity. The first space is formed by fixing a plate-like transparent substrate on the sensor substrate through the adhesive by the sensor substrate, the adhesive, and the transparent substrate. The back surface of the sensor substrate is thinned in the state fixed to the transparent substrate. The external electrode is electrically connected to the sensor section through a through-electrode provided on the sensor substrate on the thinned back surface of the sensor substrate. The second space is formed between the curved portion and the back surface of the sensor substrate by arranging the curved guide including a curved portion of a concave shape on the back surface side of the sensor substrate. The back surface of the sensor substrate is brought into contact with the curved guide by reducing an atmospheric pressure in the second space to lower than an atmospheric pressure in the first space.

Certain embodiments provide a method for manufacturing a solid-state imaging device including forming an adhesive, forming a plurality of first spaces, thinning a back surface of a wafer, forming a plurality of external electrodes, forming a second space, bringing a curved guide into contact with the back surface of the wafer, and cutting the wafer, the adhesive, a transparent substrate, and the curved guide. The adhesive is formed at a periphery of each sensor section in the surface of the wafer including a plurality of sensor sections for generating charges according to the received light quantity. The plurality of first spaces are formed by fixing a plate-like transparent substrate on the wafer through the adhesive by the wafer, the adhesive, and the transparent substrate. The back surface of the wafer is thinned in the state fixed to the transparent substrate. The plurality of external electrode are electrically connected to the respective sensor section through a plurality of through-electrodes provided on the wafer on the thinned back surface of the wafer. The second space is formed between the plurality of curved portions and the back surface of the sensor substrate by arranging the curved guide including a plurality of curved portions of a concave shape on the back surface side of the wafer. The back surface of the wafer is brought into contact with the curved guide by reducing an atmospheric pressure in the second space to lower than an atmospheric pressure in the plurality of first spaces.

The solid-state imaging device, the method for manufacturing the solid-state imaging device, and the camera module according to the embodiments will be hereinafter described.

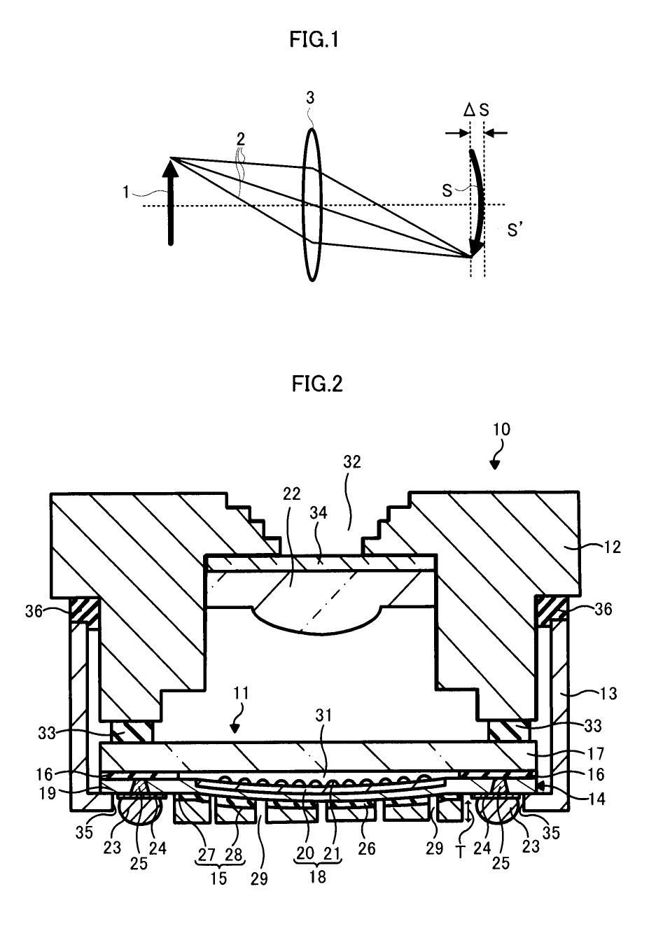

First, the principle of the present invention will be described with reference to FIG. 1. FIG. 1 is an explanatory view for describing the principle of the present invention. As shown in FIG. 1, when alight 2 reflected by an imaging target 1 is collected by a lens 3, both sides of which have a convex shape, a focal plane S formed by the focal position thereof becomes a curved rotation surface. A misalignment ΔS of the curved focal plane S and a plane S′ is referred to as a field curvature. The conventional camera module has a planar sensor section, and thus the quality of the imaged image is lowered by the field curvature ΔS.

The solid-state imaging device according to the present embodiments to be described below, on the other hand, has a curved sensor section so as to coincide with the focal plane S of the lens. Therefore, each camera module according to each embodiment applied with such solid-state imaging device can suppress the occurrence of the field curvature ΔS and provide a high quality image.

The solid-state imaging device including the curved sensor section, the method for manufacturing the solid-state imaging device, and the camera module applied with the solid-state imaging device including the curved sensor section will be described below with reference to the drawings.

### First Embodiment

FIG. 2 is a cross-sectional view showing a camera module 10 according to a first embodiment. As shown in FIG. 2, the camera module 10 includes a solid-state imaging device 11, a lens holder 12, and a shield 13.

The solid-state imaging device 11 includes a sensor substrate 14, a curved guide 15, a first adhesive 16, and a transparent substrate 17.

The sensor substrate 14 is a thinned silicon substrate 19 including a sensor section 18. The sensor section 18 is formed on a surface of the silicon substrate 19, and generates charges according to the received light quantity.

The sensor section 18 includes a photodiode layer 20 for photoelectric conversion, and a plurality of microlenses for collecting light to the photodiode layer 20. The photodiode layer 20 is formed on the surface of the silicon substrate 19, and the plurality of microlenses 21 are formed on the surface of the silicon substrate 19.

One part of the sensor substrate 14 including the sensor section 18 is curved downward to a convex shape along a curved portion 28 of the curved guide 15. The curvature of the curved sensor section 18 substantially matches the curvature of the focal plane of the lens 22, to be described later.

A plurality of external electrodes 23 electrically connected to the sensor section 18 is formed on the back surface of the sensor substrate 14. The external electrode 23 is made of a solder ball, for example.

The external electrode 23 is brought into contact with a wiring 24 formed on the back surface of the sensor substrate 14. The wiring 24 is electrically connected to the sensor section 18 through a through-electrode 25 and the like passing through the sensor substrate 14. In other words, the external electrode 23 is electrically connected to the sensor section 18 through the wiring 24 and the through-electrode 25.

The curved guide 15 has the entire surface fixed to the back surface of the sensor substrate 14 while making contact through a second adhesive 26. The curved guide 15 includes a plane portion 27 and the curved portion 28 curved to a concave shape. The curved guide 15 is made of plastic, and the thickness T thereof is thinner than the thickness (e.g., 100 to 200 μm) of the external electrode 23 in FIG. 2.

The curvature of the curved portion 28 curved to the concave shape substantially matches the curvature of the focal plane of the lens 22, to be described later. The thickness T of the curved guide 15 depends on the curvature of the focal plane of the lens 22, and hence the thickness T of the curved guide 15 becomes thick and may become thicker than the thickness of the external electrode 23 if the curvature is large. In this case, a hole or a depression is to be formed at a portion corresponding to the curved guide 15 in the substrate for mounting the camera module 10.

The plane portion 27 of the curved guide 15 is fixed to the sensor substrate 14 (planar portion of the sensor substrate 14) other than the curved portion, and the curved portion 28 is fixed to the curved portion of the sensor substrate 14. The curved portion 28 is curved to a concave shape to coincide with the shape of the curved sensor section 18.

As described above, the curvature of the curved portion 28 curved to a concave shape substantially matches the curvature of the focal plane of the lens 22, to be described later. Therefore, the curvature of the sensor section 18 to be brought into contact with the curved portion 28 also substantially matches the curvature of the focal plane of the lens 22.

One part of the sensor substrate 14 including the sensor section 18 is fixed while making contact with the curved portion 28, and thus the curvature of the sensor section 18 can always be maintained constant without depending on the surrounding environment.

The curved guide 15 may be formed from a material that suppresses the transmission of light (e.g., infrared light). In this case, the unnecessary light can be suppressed from entering inside from the lower surface of the camera module 10.

The curved portion 28 of the curved guide 15 includes a plurality of through-holes 29. As will be specifically described upon describing the method for manufacturing the solid-state imaging device 11 later, the through-holes 29 are used to have the atmospheric pressure in the second space 30 (FIG. 5) formed between the back surface of the plate-like sensor substrate 14 (FIG. 5) and the curved portion 28 of the curved guide 15 lower than that in the first space 31, to be described later.

The first adhesive 16 is formed to an annular shape so as to surround the sensor section 18 at the periphery of the sensor section 18 in the surface of the sensor substrate 14. The first adhesive 16 has a function of adhering and fixing the sensor substrate 14 and the transparent substrate 17, and at the same time, serves as a spacer.

The transparent substrate 17 is a plate-like glass substrate, for example, and is fixed on the sensor substrate 14 by the first adhesive 16. The transparent substrate 17 serves as a supporting substrate when thinning the silicon substrate 19 to become the sensor substrate 14.

The sensor substrate 14, the first adhesive 16, and the transparent substrate 17 form the first space 31, and the sensor section 18 is arranged in the first space 31.

The lens holder 12 has a tubular shape with a top plate formed with an opening 32, and is fixed on the transparent substrate 17. The lens holder 12 is fixed on the transparent substrate 17 by a third adhesive 33 formed between the open end of the lens holder 12 and the surface of the transparent substrate 17.

The lens holder 12 interiorly holds the lens 22 and an infrared cut filter 34, and is fixed on the transparent substrate 17 such that the position of the focal plane of the lens 22 coincides with the curved sensor section 18. The position in the up and down direction (in the vertical direction) of the lens holder 12 is adjusted by the thickness of the third adhesive 33.

As shown in FIG. 2, the infrared cut filter 34 may be arranged on the upper surface of the lens 22, or may be arranged on the lower surface of the lens 22 as a support of the lens holder 12. The infrared cut filter 34 may also be formed on the transparent substrate 17.

The shield 13 has a bottomed tubular shape and is fixed to the lens holder 12. The bottom portion of the shield 13 has an opening 35. The shield 13 is arranged to expose the plurality of external electrodes 23 from the opening 35 of the bottom portion and to make the bottom portion contact the back surface of the sensor substrate 14. The tubular portion of the shield 13 is arranged to cover the solid-state imaging device 11. The shield 13 arranged in such manner is fixed to the lens holder 12 by a fourth adhesive 36 formed between the open end of the tubular portion and the lens holder 12.

The shield 13 is formed from a light blocking material but may be given a function of an electromagnetic shield by further giving conductivity and grounding.

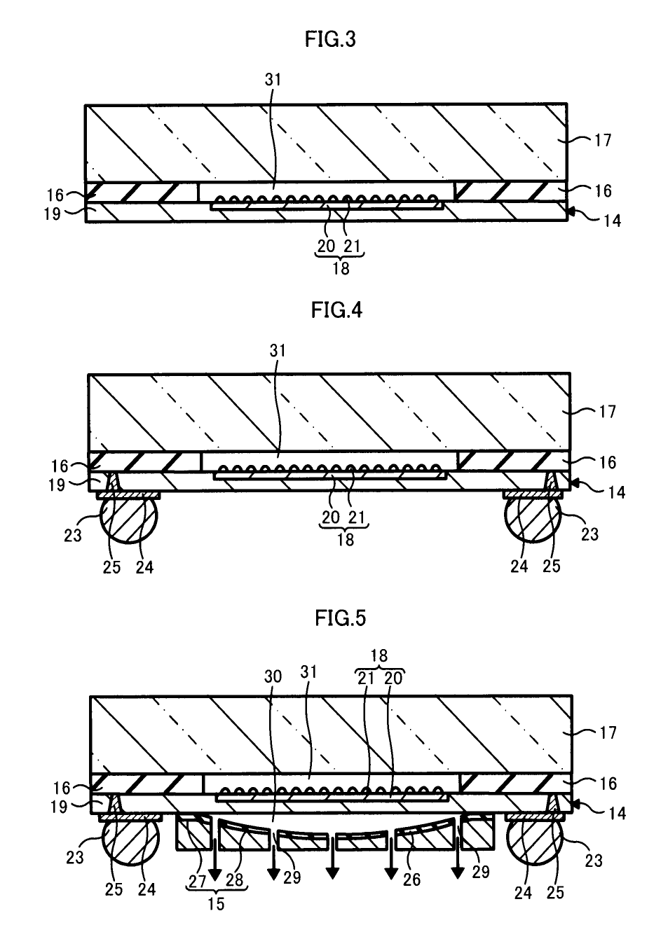

A method for manufacturing the solid-state imaging device 11 according to the present embodiment will now be described with reference to FIG. 3 to FIG. 6. FIG. 3 to FIG. 6 are cross-sectional views corresponding to FIG. 2 for describing the method for manufacturing the solid-state imaging device 11 according to the present embodiment.

First, as shown in FIG. 3, the first adhesive 16 of annular shape surrounding the sensor section 18 is formed through patterning, for example, on the surface of the sensor substrate 14 including the sensor section 18. Then, the plate-like transparent substrate 17 is fixed on the sensor substrate 14 through the first adhesive 16. The sensor substrate 14, the first adhesive 16, and the transparent substrate 17 form the first space 31.

Furthermore, the sensor substrate 14 is thinned from the back surface using the transparent substrate 17 as a supporting substrate. The sensor substrate 14 is thinned through the CMP (Chemical Mechanical Polishing) method, for example, and is thinned to a thickness of about 50 μm.

The sensor substrate 14 is prevented from breaking when curving the sensor substrate 14 in the step to be described later, and the sensor substrate 14 can be easily curved by thinning the sensor substrate 14. Furthermore, the through-electrode 25 can be easily formed by thinning the sensor substrate 14.

Then, as shown in FIG. 4, a plurality of external electrodes 23 electrically connected to the sensor section 18 is formed on the back surface of the thinned sensor substrate 14. After forming the through-electrode 25 on the sensor substrate 14 and forming the wiring 24 on the back surface of the sensor substrate 14, the external electrode 23 is formed to be brought into contact with the wiring 24.

As shown in FIG. 5, the second adhesive 26 is formed on the surface of the curved guide 15 including the plane portion 27 and the curved portion 28 of a concave shape, and then the peripheral part of the curved portion 28, that is, the plane portion 27 is fixed to the back surface of the sensor substrate 14. The second space 30 is thereby formed between the back surface of the sensor substrate 14 and the curved portion 28.

Thereafter, the second space 30 is vacuumed using a normally used depressurization mounting device (not shown), so that gas (e.g., air) in the second space 30 is suctioned from a plurality of through-holes 29 formed in the curved portion 28 of the curved guide 15. The atmospheric pressure in the second space 30 is thus reduced to lower than the atmospheric pressure in the first space 31.

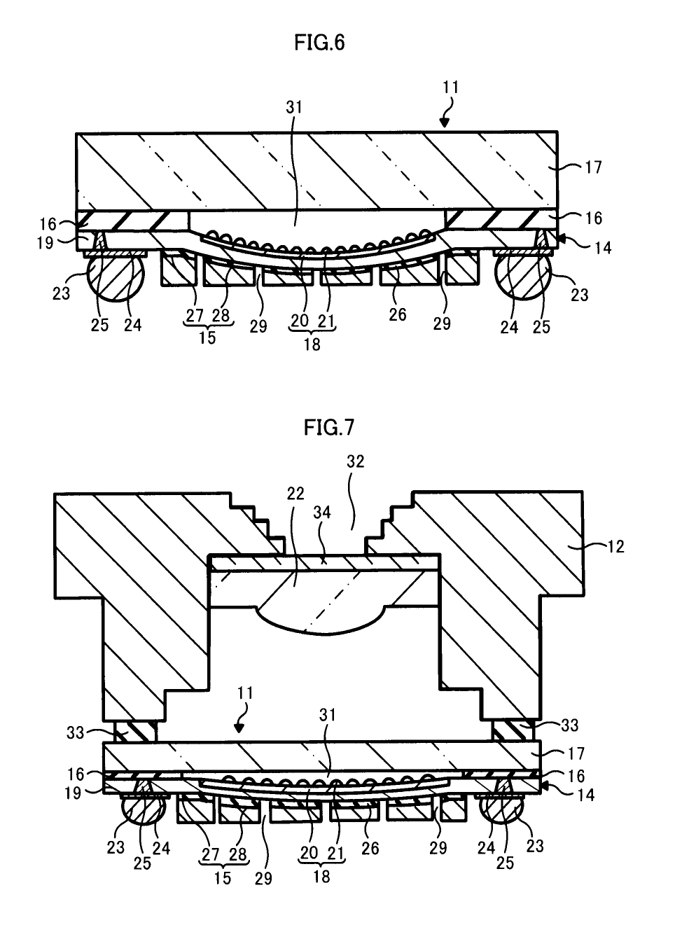

According to such step, the atmospheric pressure in the second space 30 becomes lower than the atmospheric pressure in the first space 31, and hence the thinned sensor substrate 14 curves downward to a convex shape thus making contact with the curved portion 28 of the curved guide 15, as shown in FIG. 6. The curved sensor substrate 14 is fixed to the curved portion 28 through the second adhesive 26. The solid-state imaging device 11 including the sensor section 18 curved downward to a convex shape is thereby manufactured.

A method for manufacturing the camera module 10 according to the present embodiment will now be described with reference to FIG. 7. FIG. 7 is a cross-sectional view corresponding to FIG. 2 for describing the method for manufacturing the camera module 10 according to the present embodiment.

As shown in FIG. 7, the third adhesive 33 having an annular shape is formed on the manufactured solid-state imaging device 11 (on transparent substrate 17). Then, the lens holder 12 internally holding the lens 22 and the infrared cut filter 34 is fixed on the solid-state imaging device 11 (on transparent substrate 17) through the third adhesive 33. The lens holder 12 is pushed into the third adhesive 33 to have the position in the height direction adjusted such that the focal plane of the lens 22 coincides with the curved sensor section 18, and then fixed by curing the third adhesive 33.

Lastly, the shield 13 is arranged such that the tubular portion of the shield 13 covers the solid-state imaging device 11 and the bottom portion of the shield 13 makes contact with the back surface of the sensor substrate 14, and the bottomed tubular shield 13 is fixed to the lens holder 12 with the fourth adhesive 36. The camera module 10 according to the present embodiment shown in FIG. 2 is thereby manufactured.

In the solid-state imaging device, the method for manufacturing the solid-state imaging device, and the camera module according to the present embodiment described above, one part of the sensor substrate 14 including the sensor section 18 is curved downward to a convex shape to coincide with the focal plane of the curved lens 22. Therefore, the occurrence of the field curvature can be suppressed, and a high quality solid-state imaging device, a method for manufacturing the high quality solid-state imaging device, and a high quality camera module can be provided.

Furthermore, according to the camera module of the present embodiment, the quality of the camera module can be enhanced without using a plurality of lenses for correcting the field curvature since the solid-state imaging device in which one part of the sensor substrate 14 including the sensor section 18 is curved downward to a convex shape is applied. Therefore, a high quality and low cost camera module can be provided.

According to the solid-state imaging device, the method for manufacturing the solid-state imaging device, and the camera module of the present embodiment, the sensor substrate 14 is curved by having the atmospheric pressure in the second space 30 formed between the curved guide 15 and the back surface of the sensor substrate 14 lower than the atmospheric pressure in the first space 31 formed between the sensor substrate 14 and the transparent substrate 17. Therefore, the sensor section 18 can be prevented from being scratched such as the microlens 21 of the sensor section 18 deforming and damaging when curving the sensor substrate 14, so that a higher quality solid-state imaging device, a method for manufacturing the higher quality solid-state imaging device, and a higher quality camera module can be provided.

### Second Embodiment

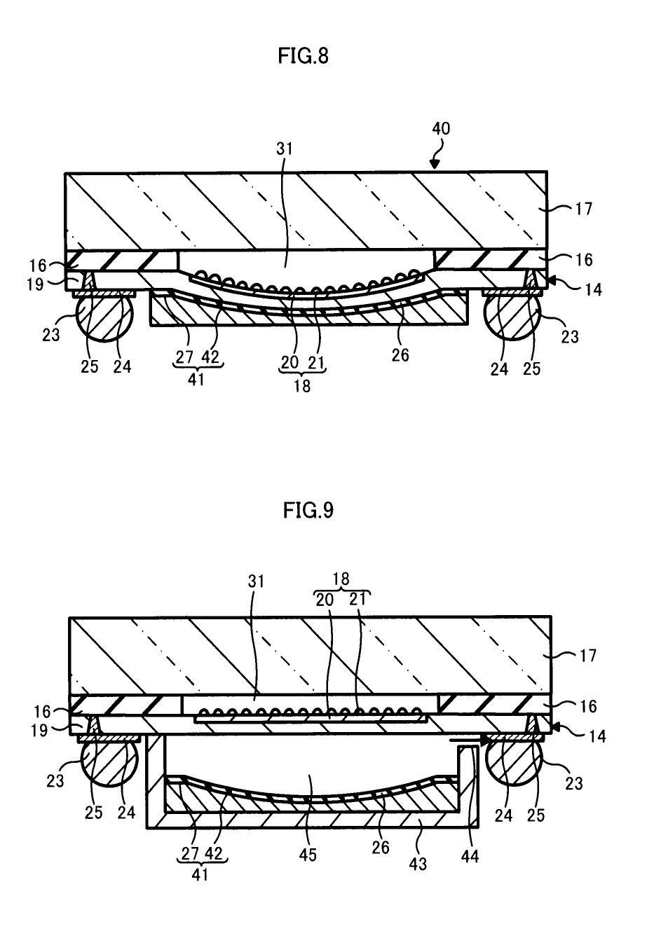

FIG. 8 is a cross-sectional view showing a solid-state imaging device 40 to be applied to a camera module according to a second embodiment. The solid-state imaging device 40 differs from the solid-state imaging device 11 applied to the camera module 10 according to the first embodiment in that a through-hole is not provided at a curved portion 42 of a curved guide 41, but others are all the same. Therefore, the description on the structure of the solid-state imaging device 40 shown in FIG. 8 will be omitted.

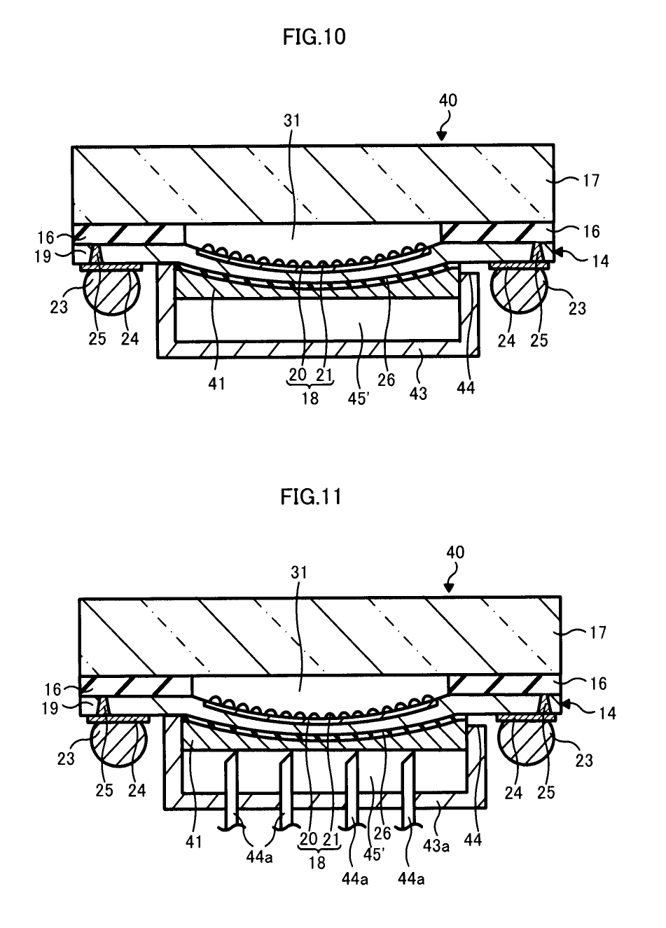

The method for manufacturing the solid-state imaging device according to the second embodiment will now be described with reference to FIG. 9 and FIG. 10. FIG. 9 and FIG. 10 are cross-sectional views corresponding to FIG. 8 for describing the method for manufacturing the solid-state imaging device according to the present embodiment. The manufacturing method differs from the method for manufacturing the solid-state imaging device 11 according to the first embodiment in the step of fixing the curved guide 41 on the back surface of the sensor substrate 14, but others are all the same. Therefore, the step of fixing the curved guide 41 to the back surface of the sensor substrate 14 will be described in the following description.

As shown in FIG. 4, after forming the solid-state imaging device including the sensor substrate 14 in a plate-like state, the curved guide 41 having the second adhesive 26 applied to the surface is arranged in a vacuum container 43, as shown in FIG. 9. The vacuum container 43 includes a recessed portion 44 at one part of the open end of the container 43. The open end of the vacuum container 43 in which the curved guide 41 is arranged is brought into contact with the back surface of the sensor substrate 14. Thereafter, the gas (e.g., air) in the vacuum container 43, that is, the second space 45 formed by the back surface of the sensor substrate 14, the vacuum container 43, and the curved guide 41 is suctioned and vacuumed from the recessed portion 44 of the vacuum container 43 to reduce the atmospheric pressure in the second space 45 to lower than the atmospheric pressure in the first space 31.

When the atmospheric pressure in the second space 45 is lowered, the curved guide 41 is moved upward in the container 43, and the curved guide 41 is fixed to the back surface of the sensor substrate 14 through the second adhesive 26, as shown in FIG. 10. One part of the sensor substrate 14 fixed with the curved guide 41 is curved along the curved portion 42 of the curved guide 41. Thus, the solid-state imaging device 40 in which one part of the sensor substrate 14 including the sensor section 18 is curved downward to a convex shape is manufactured.

When reducing the atmospheric pressure in the second space 45, the atmospheric pressure in the second space 45 is selected to become the atmospheric pressure such that the curvature radius of the back surface of the sensor section 14 becomes smaller than the curvature radius of the curved portion 42 of the curved guide 41. In this case, the adhesion from the back surface of the central part of the sensor section 14 to the curved portion 42 starts, and the adhesion to the curved portion 42 advances in order along the direction from the central part to the peripheral part of the sensor section 14.

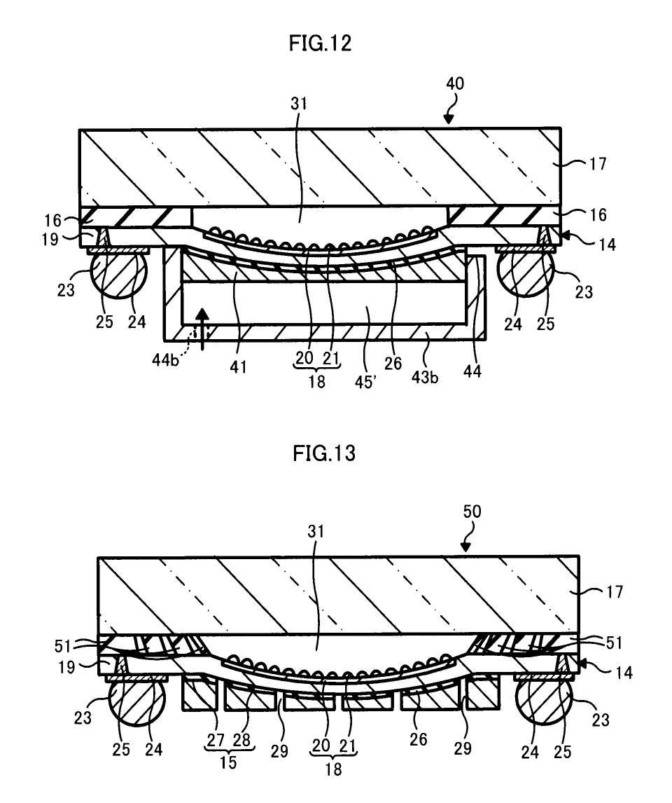

In this step, when the curved guide 41 starts to move upward in the container 43, a space 45′ is formed between the back surface of the curved guide 41 and the bottom portion of the vacuum container 43, as shown in FIG. 10. The pressure to push the curved guide 41 lacks depending on the atmospheric pressure in the space 45′. In this case, a mechanism for pushing up the curved guide 41 from below may be added to the vacuum container 43. FIG. 11 and FIG. 12 are cross-sectional views corresponding to FIG. 9 showing the vacuum containers 43a, 43b including a mechanism for pushing up the curved guide 41 from below.

As shown in FIG. 11, pins 44a for pushing up the curved guide 41 from below may be added to the vacuum container 43a as the mechanism for pushing up the curved guide 41 from below.

As shown in FIG. 12, a through-hole 44b for injecting gas to the space 45′ between the back surface of the curved guide 41 and the bottom portion of the vacuum container 43 may be arranged at the bottom portion of the vacuum container 43b as the mechanism for pushing up the curved guide 41 from below. The atmospheric pressure in the space 45′ may be raised by applying the gas pressure through the through-hole 44b at the bottom portion to push up the curved guide 41.

After the solid-state imaging device 40 is manufactured, the lens holder 12 is fixed, and then the shield 13 is fixed, similar to the method for manufacturing the camera module 10 according to the first embodiment. The camera module according to the second embodiment is thereby manufactured.

In the solid-state imaging device, the method for manufacturing the solid-state imaging device, and the camera module according to the present embodiment described above as well, the occurrence of field curvature can be suppressed since one part of the sensor substrate 14 including the sensor section 18 is curved downward to a convex shape, and the high quality solid-state imaging device, the method for manufacturing the high quality solid-state imaging device, and the high quality camera module can be provided.

Furthermore, in the camera module according to the present embodiment as well, a high quality and low cost camera module can be provided since the solid-state imaging device in which one part of the sensor substrate 14 including the sensor section 18 is curved downward to a convex shape is applied.

The sensor substrate 14 is curved using the air pressure difference in the solid-state imaging device, the method for manufacturing the solid-state imaging device, and the camera module according to the present embodiment as well. Therefore, the sensor section 18 can be prevented from being scratched when curving the sensor substrate 14, so that a higher quality solid-state imaging device, a method for manufacturing the higher quality solid-state imaging device, and a higher quality camera module can be provided.

### Third Embodiment

FIG. 13 is a cross-sectional view showing a solid-state imaging device 50 to be applied to a camera module according to a third embodiment. The solid-state imaging device 50 differs from the solid-state imaging device 11 applied to the camera module 10 according to the first embodiment in that first adhesives 51 are arranged so as to be spaced apart from each other. The respective first adhesive 51 is arranged to an annular form to surround the sensor section 18 at the periphery of the sensor section 18 in the surface of the sensor substrate 14.

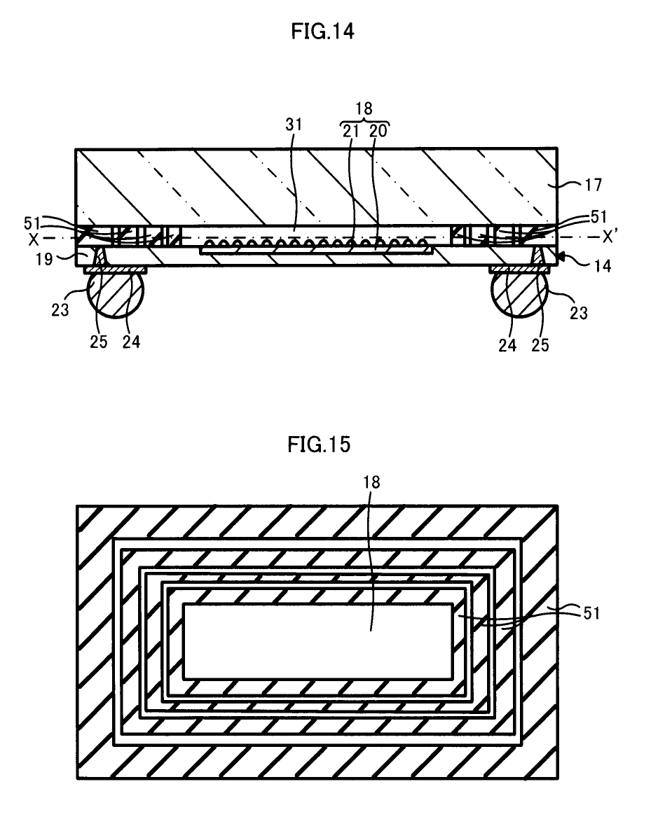

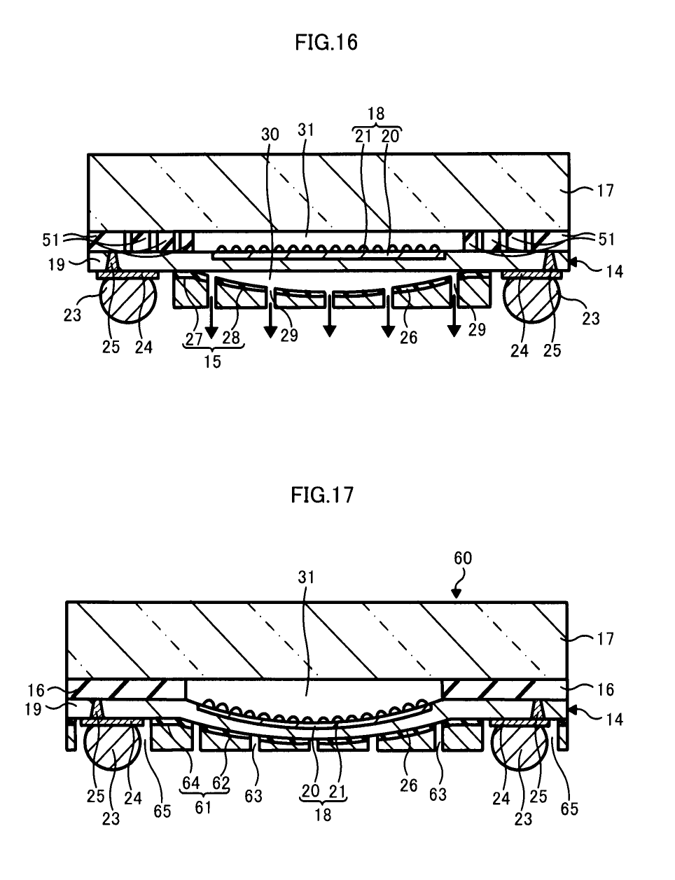

The method for manufacturing the solid-state imaging device according to the third embodiment will now be described with reference to FIG. 14, FIG. 15, and FIG. 16. FIG. 14 and FIG. 16 are cross-sectional views corresponding to FIG. 13 for describing the method for manufacturing the solid-state imaging device according to the present embodiment. FIG. 15 is a cross-sectional view of the first adhesives 51 taken along a chain dashed line X-X′ in FIG. 14.

As shown in FIG. 14 and FIG. 15, a plurality of annular first adhesives 51 are formed to surround the respective sensor section 18 at the periphery of the sensor section 18 in the surface of the sensor substrate 14 including the sensor section 18. Such first adhesives 51 are formed at positions spaced apart from each other. Then, the plate-like transparent substrate 17 is fixed on the sensor substrate 14 through the first adhesives 51, and the sensor substrate 14 is thinned from the back surface using the transparent substrate 17 as a supporting substrate. The plurality of external electrodes 23 electrically connected to the sensor section 18 are formed on the back surface of the thinned sensor substrate 14.

As shown in FIG. 16, after forming a second adhesive 26 on the surface of the curved guide 15 including the plane portion 27 and the curved portion 28 of a concave shape, the peripheral portion of the curved portion 28, that is, the plane portion 27 is fixed to the back surface of the sensor substrate 14. The second space 30 is thereby formed between the back surface of the sensor substrate 14 and the curved portion 28.

Then, the gas (e.g., air) in the second space 30 is suctioned from a plurality of through-holes 29 formed in the curved portion 28 of the curved guide 15 to reduce the atmospheric pressure in the second space 30 to lower than the atmospheric pressure in the first space 31. According to such step, the sensor substrate 14 is curved, and the curved portion 28 is fixed to the back surface of the curved sensor substrate 14 through the second adhesive 26. The solid-state imaging device 50 including the sensor section 18 curved downward to a convex shape is thereby manufactured.

After manufacturing the solid-state imaging device 50, the lens holder 12 is fixed, and then the shield 13 is fixed, similar to the method for manufacturing the camera module 10 according to the first embodiment. The camera module according to the third embodiment is thereby manufactured.

In the steps shown in FIG. 14 and FIG. 15, the plurality of first adhesives 51 are formed for the following reasons.

In the step shown in FIG. 16, the sensor substrate 14 is fixed to the plane portion 27 of the curved guide 15, and then is started to be curved from the portion corresponding to the peripheral portion of the curved portion 28 along the curved portion 28 of the curved guide 15. When the curving of the sensor substrate 14 starts, a stress generates towards the central direction of the sensor substrate 14 at a portion where the sensor substrate 14 and the first adhesive 51 are brought into contact.

If the first adhesive 16 is formed as in the method for manufacturing the solid-state imaging device according to the first embodiment, the surface of the sensor substrate 14 may distort due to the stress as the curving of the sensor substrate 14 advances in the step shown in FIG. 5. This stress becomes greater towards the middle of the sensor substrate 14 of the portion where the surface of the sensor substrate 14 and the first adhesive 16 are brought into contact. Therefore, the portion corresponding to the boundary portion of the plane portion 27 and the curved portion 28 of the curved guide 15 of the surface of the sensor substrate 14 may especially distort greatly. If the surface of the sensor substrate 14 distorts, the circuit pattern provided on the surface of the sensor substrate 14 may also distort, and the properties of the manufactured solid-state imaging device may degrade.

In order to suppress the degradation of the properties of the solid-state imaging device, the circuit pattern is to be formed at portions where distortion does not occur without forming at the corresponding portion. However, with this means, the layout of the circuit pattern becomes restricted, and the dimension of the sensor substrate 14 may become large.

However, in the solid-state imaging device 50 according to the present embodiment, if the plurality of first adhesives 51 is formed so as to be spaced apart from each other, the plurality of first adhesives 51 distort towards the central direction of the sensor substrate 14, as shown in FIG. 13, as the curving of the sensor substrate 14 advances. Therefore, the surface of the sensor substrate 14 is suppressed from being distorted.

In other words, the plurality of first adhesives 51 are formed to suppress the surface of the sensor substrate 14 from being distorted when curving the sensor substrate 14.

In the solid-state imaging device, the method for manufacturing the solid-state imaging device, and the camera module according to the present embodiment described above as well, the occurrence of field curvature can be suppressed since one part of the sensor substrate 14 including the sensor section 18 is curved downward to a convex shape, and a high quality solid-state imaging device, a method for manufacturing the high quality solid-state imaging device, and a high quality camera module can be provided.

Furthermore, in the camera module according to the present embodiment as well, a high quality and low cost camera module can be provided since the solid-state imaging device in which one part of the sensor substrate 14 including the sensor section 18 is curved downward to a convex shape is applied.

Furthermore, the sensor substrate 14 is curved using the air pressure difference in the solid-state imaging device, the method for manufacturing the solid-state imaging device, and the camera module according to the present embodiment. Therefore, sensor section 18 can be prevented from being scratched when curving the sensor substrate 14, so that a higher quality solid-state imaging device, a method for manufacturing the higher quality solid-state imaging device, and a higher quality camera module can be provided.

### Fourth Embodiment

FIG. 17 is a cross-sectional view showing a solid-state imaging device 60 to be applied to a camera module according to a fourth embodiment. The solid-state imaging device 60 is the same as the solid-state imaging device 11 to be applied to the camera module 10 according to the first embodiment in that a plurality of through-holes 63 is formed in a curved portion 62 of a curved guide 61, but differs in further including a second through-hole 65 in a plane portion 64 to expose the external electrode 23 from the second through-hole 65. Other structures are all the same. Therefore, the description on the structure of the solid-state imaging device 60 shown in FIG. 17 will be omitted.

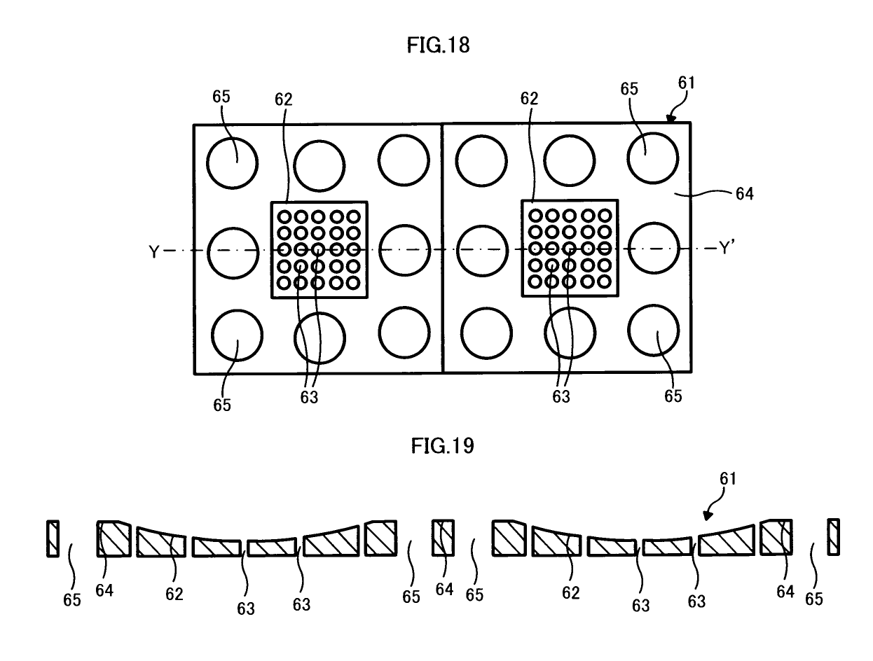

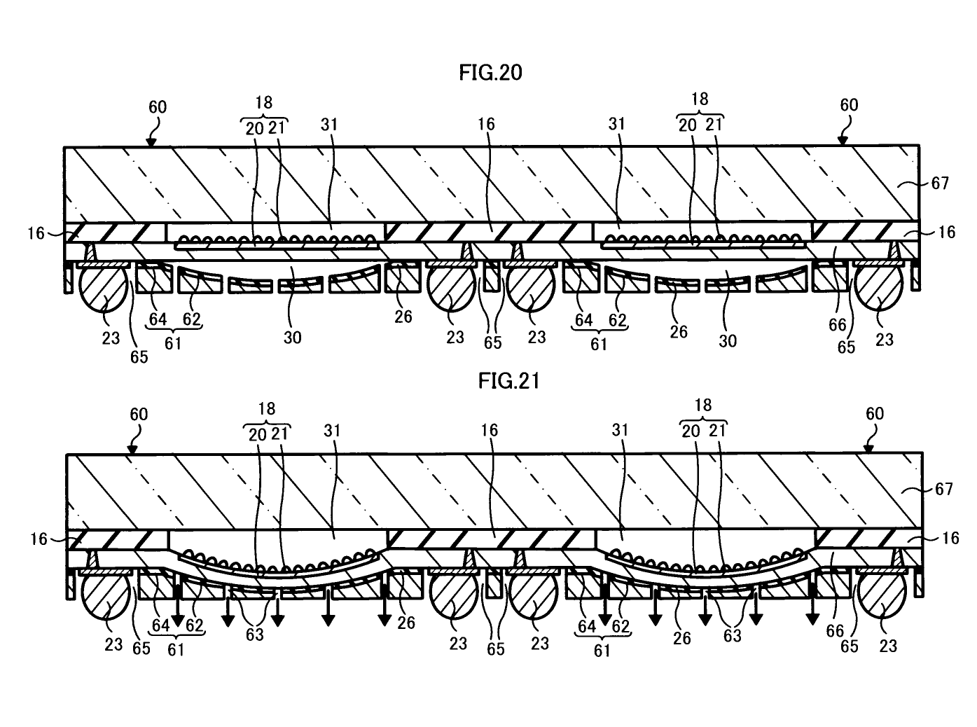

A method for manufacturing the solid state imaging device according to the fourth embodiment will now be described with reference to FIG. 18 to FIG. 22. FIG. 18 and FIG. 19 are views showing the curved guide 61 applied to the manufacturing method, where FIG. 18 is a top view and FIG. 19 is a cross-sectional view taken along a chain dashed line Y-Y′ of FIG. 18. FIG. 20 to FIG. 22 are cross-sectional views corresponding to FIG. 17 for describing the method for manufacturing the solid-state imaging device according to the present embodiment. The manufacturing method differs from the method for manufacturing the solid-state imaging device 11 according to the first embodiment in that a plurality of solid-state imaging devices 60 is collectively formed on one wafer. The method for collectively forming the plurality of solid-state imaging devices 60 is a method in which the manufacturing cost can be greatly reduced since the manufacturing efficiency of the solid-state imaging device can be enhanced compared to the method of attaching the curved guides 15, 41 to each individualized solid-state imaging device 11, 40, 50 as in the method for manufacturing the solid-state imaging device according to the first to third embodiments.

First, the curved guide 61 applied in the method for manufacturing the solid-state imaging device according to the present embodiment will now be described with reference to FIG. 18 and FIG. 19. As shown in FIG. 18 and FIG. 19, the curved guide 61 includes a plane portion 64 and a plurality of curved portions 62. Each curved portion 62 includes a plurality of first through-holes 63, similar to the curved guide 15 shown in FIG. 2 and the like.

The curved guide 61 includes a plurality of second through-holes 65 in the plane portion 64. Such second through-holes 65 are through-holes formed to expose the external electrode 23 when the curved guide 61 is fixed to the back surface of the sensor substrate 14.

Such curved guide 61 may be obtained by integrally forming the plurality of curved guides having a shape (but includes second through-hole 65) similar to the curved guide 15 shown in FIG. 2 and the like with a hanging pin or the like, or forming a plurality of curved portions 62, and the first and second through-holes 63, 65 in one planar plate.

The method for manufacturing the solid-state imaging device according to the present embodiment will now be described with reference to FIG. 20 to FIG. 22.

First, a plurality of solid-state imaging devices 60 is collectively formed in one wafer, as shown in FIG. 20. In other words, a plurality of sensor sections 18 is formed in a silicon wafer 66, which is to become a silicon substrate later, a first adhesive 16 is formed at a periphery of each sensor section 18 to surround each sensor section 18, and then a wafer 67 having transparency such as a glass wafer, which is to become a transparent substrate later, is fixed on the silicon wafer 66. Thereafter, the silicon wafer 66 is thinned, and a plurality of external electrodes 23 is formed on the back surface of the silicon wafer 66 to be electrically connected to each sensor section 18.

Subsequently, a second adhesive 26 is formed on the surface of the curved guide 61 shown in FIG. 18 and FIG. 19, and the peripheral portion of the respective curved portion 62, that is, the plane portion 64 is fixed to the back surface of the silicon wafer 67. Here, the external electrode 23 is exposed from the second through-hole 65. The second spaces 30 are thus formed between the back surface of the silicon wafer 66 and the plurality of curved portions 62.

Thereafter, the second space 30 is vacuumed using a normally used depressurization mounting device (not shown), as shown in FIG. 21, so that gas (e.g., air) in the second spaces 30 is suctioned from a plurality of first through-holes 63 formed in the curved portion 62 of the curved guide 61. The atmospheric pressure in the second spaces 30 is thus reduced to lower than the atmospheric pressure in the corresponding first spaces 31.

According to such step, the atmospheric pressure in the second space 30 becomes lower than the atmospheric pressure in the first space 31, and hence the portion including the sensor section 18 of the thinned silicon wafer 66 curves downward to a convex shape thus making contact with the curved portion 62 of the curved guide 61. Each curved portion 62 is fixed to the back surface of the curved silicon wafer 66 through the second adhesive 26. The plurality of solid-state imaging devices 60 including the sensor section 18 curved downward to a convex shape are thereby manufactured.

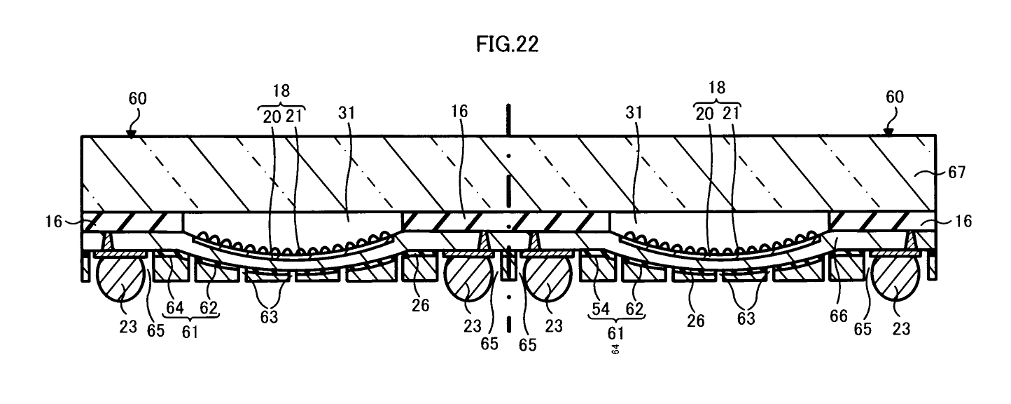

Then, as shown in FIG. 22, the wafer 67 having transparency, the second adhesive 26, the silicon wafer 66, and the curved guide 61 are cut along a scribe line (along chain dashed line in the figure). The plurality of solid-state imaging devices 60 are thereby divided into plurals.

If a collection of a plurality of curved guides is applied as the curved guide 61, the cutting in the relevant step refers to dividing the collection of the curved guides into an individual curved guide.

After the solid-state imaging device 60 is manufactured in such manner, the lens holder 12 is fixed, and then the shield 13 is fixed, similar to the method for manufacturing the camera module 10 according to the first embodiment. The camera module according to the fourth embodiment is thereby manufactured.

In the solid-state imaging device, the method for manufacturing the solid-state imaging device, and the camera module according to the present embodiment described above as well, the occurrence of field curvature can be suppressed since one part of the sensor substrate 14 including the sensor section 18 is curved downward to a convex shape, and a high quality solid-state imaging device, a method for manufacturing the high quality solid-state imaging device, and a high quality camera module can be provided.

Furthermore, in the camera module according to the present embodiment as well, a high quality and low cost camera module can be provided since the solid-state imaging device in which one part of the sensor substrate 14 including the sensor section 18 is curved downward to a convex shape is applied.

Furthermore, the sensor substrate 14 is curved using the air pressure difference in the solid-state imaging device, the method for manufacturing the solid-state imaging device, and the camera module according to the present embodiment. Therefore, the sensor section 18 can be prevented from being scratched when curving the sensor substrate 14, so that a higher quality solid-state imaging device, a method for manufacturing the higher quality solid-state imaging device, and a higher quality camera module can be provided.

In the method for manufacturing the solid-state imaging device according to the fourth embodiment, the method for manufacturing the solid-state imaging device according to the second or third embodiment may be applied, and the method of curving the silicon wafer 66 may be applied. Effects similar to the above are also obtained in this case.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For instance, the lens holder and the shield of the camera module of the present invention are not limited to the lens holder 12 and the shield 13 applied to the camera module of each embodiment.

The embodiments described above relates to a compact camera module to be mounted on a portable telephone, and the like, but the solid-state imaging device described above may be applied instead of the CCD sensor or the CMOS sensor as a sensor for a camera such as a digital camera mounted with the CCD sensor or the CMOS sensor within a normal external casing. If the solid-state imaging device described above is applied as a sensor for the camera, the lens load of the optical system of the camera can be alleviated.

What is claimed is:

1. A solid-state imaging device comprising:
a curved guide including a curved portion of a concave shape;
a sensor substrate including a sensor section, for receiving a light collected by a lens and generating charges in accordance with a light receiving quantity, on a surface, having the curved guide fixed on a back surface, and having a region including the sensor section curved downward to a convex shape along the curved portion of the curved guide;
an adhesive formed at a periphery of the sensor section in the surface of the sensor substrate so as to surround the sensor section;
a plate-like transparent substrate fixed on the sensor substrate by the adhesive; and
an external electrode formed on the back surface of the sensor substrate, and electrically connected to the sensor section through a through-electrode provided on the sensor substrate.

2. The solid-state imaging device according to claim 1, wherein the curved portion is curved at a curvature that matches a curvature of a focal plane of the lens.

3. The solid-state imaging device according to claim 1, wherein the curved guide includes a plurality of through-holes in the curved portion.

4. The solid-state imaging device according to claim 1, wherein the adhesive is formed in plurals spaced apart from each other at the periphery of the sensor section in the surface of the sensor substrate so as to surround the sensor section.

5. A camera module comprising:
the solid-state imaging device according to claim 1;
a tubular lens holder fixed on the transparent substrate of the solid-state imaging device;
a lens held in the lens holder; and
a tubular shield, fixed to the lens holder, for covering the sensor substrate and the transparent substrate.

6. A method for manufacturing a solid-state imaging device, the method comprising:
forming an adhesive at a periphery of a sensor section in a surface of a sensor substrate including the sensor section, for receiving a light collected by a lens and generating charges according to a light receiving quantity, so as to surround the sensor section;
fixing a plate-like transparent substrate on the sensor substrate through the adhesive to form a first space by the sensor substrate, the adhesive, and the transparent substrate;
thinning a back surface of the sensor substrate fixed to the transparent substrate;
forming an external electrode electrically connected to the sensor section through a through-electrode provided on the sensor substrate on the back surface of the thinned sensor substrate;
arranging a curved guide including a curved portion of a concave shape on the back surface side of the sensor substrate to form a second space between the curved portion and the back surface of the sensor substrate; and
bringing the back surface of the sensor substrate into contact with the curved guide and then fixing by reducing an atmospheric pressure in the second space to lower than an atmospheric pressure in the first space.

7. The method for manufacturing the solid-state imaging device according to claim 6, wherein
the second space is formed between the curved portion and the back surface of the sensor substrate by arranging the curved guide including a plurality of through-holes in the curved portion so that a periphery of the curved portion is closely adhered to the back surface of the sensor substrate; and
the back surface of the sensor substrate is brought into contact with the curved guide by suctioning gas in the second space from the plurality of through-holes of the curved guide to reduce the atmospheric pressure in the second space to lower than the atmospheric pressure in the first space.

8. The method for manufacturing the solid-state imaging device according to claim 6, wherein
the second space is formed by the curved guide, the back surface of the sensor substrate, and a container by arranging the curved guide inside the container having a recessed portion at an open end, and then closely adhering the open end excluding the recessed portion to the back surface of the sensor substrate; and
the back surface of the sensor substrate is brought into contact with the curved guide by suctioning gas in the second space from the recessed portion of the container to reduce the atmospheric pressure in the second space to lower than the atmospheric pressure in the first space.

9. The method for manufacturing the solid-state imaging device according to claim 8, wherein
the container is a container having a mechanism for pushing up the curved guide; and
the back surface of the sensor substrate is brought into contact with the curved guide by reducing the atmospheric pressure in the second space and pushing up the curved guide with the mechanism for pushing up the curved guide.

10. The method for manufacturing the solid-state imaging device according to claim 9, wherein the mechanism for pushing up the curved guide is a pin for pushing up the curved guide.

11. The method for manufacturing the solid-state imaging device according to claim 9, wherein the mechanism for pushing up the curved guide is a through-hole, formed at a bottom surface of the container, for injecting gas to a space between the bottom surface of the container and the back surface of the curved guide.

12. The method for manufacturing the solid-state imaging device according to claim 6, wherein the adhesive is composed of a plurality of adhesives spaced apart from each other; and
the plurality of adhesives are formed at a periphery of the sensor section in the surface of the sensor substrate so as to surround the sensor section.

13. A method for manufacturing a solid-state imaging device, the method comprising:
forming an adhesive at a periphery of each sensor section in a surface of a wafer including a plurality of sensor section for generating charges according to a received light quantity so as to surround each sensor section;
fixing a plate-like transparent substrate on the wafer through the adhesive to form a plurality of first spaces by the wafer, the adhesive, and the transparent substrate;
thinning a back surface of the wafer fixed to the transparent substrate;
forming a plurality of external electrodes electrically connected to the respective sensor section through a plurality of through-electrodes provided in the wafer on the back surface of the thinned wafer;
arranging a curved guide including a plurality of curved portions of a concave shape on the back surface side of the wafer to form a second space between the plurality of curved portions and the back surface of the sensor substrate;
bringing the back surface of the wafer into contact with the curved guide by reducing an atmospheric pressure in the second space to lower than an atmospheric pressure in the plurality of first spaces; and
cutting the wafer, the adhesive, the transparent substrate, and the curved guide.

14. The method for manufacturing the camera module according to claim 13, wherein the second space is composed of second spaces;
the second spaces are formed between the plurality of curved portions and the back surface of the wafer by arranging the curved guide including a plurality of through-holes in the respective curved portion so that a periphery of the plurality of curved portions is closely adhered to the back surface of the wafer; and
the back surface of the wafer is brought into contact with the curved guide by suctioning gas in the second spaces from the plurality of through-holes of the curved guide to reduce an atmospheric pressure in the second spaces to lower than an atmospheric pressure in the first spaces.

15. The method for manufacturing the camera module according to claim 13, wherein
the second space is formed by the curved guide, the back surface of the wafer, and a container by arranging the curved guide inside the container including a through-hole, and then closely adhering the container to the back surface of the wafer; and
the back surface of the wafer is brought into contact with the curved guide by suctioning gas in the second space from the through-hole of the container to reduce the atmospheric pressure in the second space to lower than the atmospheric pressure in the first spaces.

16. The method for manufacturing the solid-state imaging device according to claim 15, wherein
the container is a container having a mechanism for pushing up the curved guide; and
the back surface of the wafer is brought into contact with the curved guide by reducing the atmospheric pressure in the second space and pushing up the curved guide with the mechanism for pushing up the curved guide.

17. The method for manufacturing the solid-state imaging device according to claim 16, wherein the mechanism for pushing up the curved guide is a pin for pushing up the curved guide.

18. The method for manufacturing the solid-state imaging device according to claim 16, wherein the mechanism for pushing up the curved guide is a through-hole, formed at a bottom surface of the container, for injecting gas to a space between the bottom surface of the container and the back surface of the curved guide.

19. The method for manufacturing the solid-state imaging device according to claim 13, wherein the adhesive is composed of a plurality of adhesives spaced apart from each other; and
the plurality of adhesives are formed at a periphery of each sensor section in the surface of the wafer so as to surround each sensor section.
